(19) United States
(12) Patent Application Publication
(10) Pub. No.: US 2007/0296311 A1
(43) Pub. Date: Dec. 27, 2007

(54) Piezoelectric actuator and manufacturing method thereof, magnetic disk apparatus

(75) Inventors: Shigeyoshi Umemiya, Kawasaki (JP); Masaharu Hida, Kawasaki (JP); Masao Kondo, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/541,557

(22) Filed: Oct. 3, 2006

(30) Foreign Application Priority Data
Jun. 22, 2006 (JP) 2006-172829

(51) Int. Cl. H01L 41/00

(52) U.S. Cl. 310/365

(57) ABSTRACT

A piezoelectric actuator comprises a body of a piezoelectric material, electrode patterns embedded in the body, and a sidewall protective film of a piezoelectric material covering at least a sidewall surface of the body, the sidewall protective film covering the electrode patterns at the sidewall surface of the body.

### CROSS-REFERENCE TO RELATED APPLICATION

The present application is based on Japanese priority application No.2006-172829 filed on Jun. 22, 2006, the entire contents of which are hereby incorporated by reference.

### BACKGROUND OF THE INVENTION

The present invention generally relates to piezoelectric actuators and more particularly to a highly miniaturized and reliable piezoelectric actuator and a magnetic disk apparatus that uses such a piezoelectric actuator.

With recent trend of downsizing accompanied with augmentation of functional versatility in the information processing apparatuses, there is a demand for small and low-cost actuators capable of moving an object for minute distance but with high precision and high speed.

With an inkjet recording head of inkjet printers or a magnetic head of a magnetic disk apparatus, for example, there is a need for such a piezoelectric actuator capable of moving an object for minute distance with high precision and at high speed. Such a piezoelectric actuator is needed also in optical heads of optical disk apparatuses for focusing compensation or tilt control of the optical system used therein.

In these applications, it should be noted that the piezoelectric actuator itself is miniaturized with downsizing of the apparatus, and associated with this, the piezoelectric substance constituting the piezoelectric actuator also has a reduced layer thickness.

With such a piezoelectric actuator that uses a piezoelectric substance of small layer thickness, there is a tendency that the electric field applied to the piezoelectric substance is increased with decrease of the layer thickness. Thus, securing a reliable operation becomes a paramount problem with such a piezoelectric actuator.

In the case of the piezoelectric actuator used in magnetic disk apparatuses, in particular, the control distance or “stroke” required for the piezoelectric actuator is large, and thus, a very large electric field is applied to the piezoelectric substance. Further, the magnetic disk apparatuses have to guarantee proper operation also in various environmental conditions including high temperature and high humidity ambient, and thus, a particularly stringent demand is imposed for the piezoelectric actuator that is used in such a magnetic disk apparatus with regard to the reliability under various environmental conditions.

### Patent Reference 1

Japanese Laid-Open Patent Application 2004-30823 official gazette

### Patent Reference 2

Japanese Laid-Open Patent Application 2003-284362 official gazette

### Patent Reference 3

Japanese Laid-Open Patent Application 2003-61370 official gazette

### Patent Reference 4

Japanese Laid-Open Patent Application 2002-71871 official gazette

### Patent Reference 5

Japanese Laid-Open Patent Application 3-155180 official gazette

### Patent Reference 6

Japanese Laid-Open Patent Application 2002-319715 official gazette

### SUMMARY OF THE INVENTION

FIG. 1 shows the construction of a piezoelectric actuator 10 according to a related art of the present invention.

Referring to FIG. 1, the piezoelectric actuator 10 has a construction in which piezoelectric substance 11, 13, 15, 17 and 19 of PZT (Pb(Zr,Ti)O₃), PNN(Pb(Ni_{1/3}Nb_{2/3})O₃)_{0.5}, or the like, are laminated with each other with intervening electrode patterns 12, 14, 16 and 18 of Pt, or the like, to form a piezoelectric laminated body, wherein the piezoelectric laminated body causes expansion or shrinkage in the upward and downward directions as shown in FIG. 1 or in the longitudinal direction when a drive voltage is applied to the electrode patterns 12, 14, 16 and 18.

Further, electrode films 10A and 10B of Au, or the like, are provided at both ends of the piezoelectric laminated body.

Generally, such piezoelectric substance 11, 13, 15, 17 and 19 are formed by a green sheet process and the electrode patterns 12, 14, 16 and 18 are formed by a screen-printing process.

Meanwhile, with the piezoelectric actuator of such a construction, it should be noted that the electrode patterns 12, 14, 16 and 18 are exposed at the sidewall surfaces of the piezoelectric actuator, and because of this, such a construction raises a problem that the insulation resistance of the piezoelectric actuator is degraded severely at the sidewall surfaces thereof, particularly when the piezoelectric actuator is operated in a high temperature and high humidity ambient. Such severe degradation of insulation resistance leads to the problem of insulation breakdown.

It is thought that such severe degradation of insulation resistance is caused by a mechanism that there is caused a concentration of electric field at such a sidewall surface of the piezoelectric actuator where the electrode patterns are exposed and that such concentration of electric field facilitates the adversary process of electromigration, or the like.

When such insulation breakdown is caused at the sidewall surfaces of the piezoelectric actuator, the electrode patterns 12, 14, 16 and 18 may cause short circuit at the sidewall surfaces of the piezoelectric actuator.

As noted before, the problem of degradation of insulation resistance, and hence degradation of withstand voltage, is facilitated particularly in the high humidity ambient, and thus, there arise cases in which a piezoelectric actuator, operable stably for long time in a dry high temperature ambient, shows a serious degradation of insulation resistance after running only for about 100 hours in a high humidity ambient. As noted before, such severe degradation of insulation resistance is believed to be caused by water molecules of the ambient adsorbed on the sidewall surface of the laminated piezoelectric body and causing acceleration of electromigration.

Thus, in order to avoid insulation breakdown of the piezoelectric actuator at the sidewall surfaces thereof, Patent References 5 and 6 teach a technology of covering the sidewall surfaces of the piezoelectric laminated body constituting the piezoelectric actuator with various protective films.

When such a sidewall protective film is formed by an organic insulation film, however, there are cases in which the withstand voltage of the organic insulation film is lower than that of the piezoelectric substance itself and the protective film causes insulation breakdown first when the piezoelectric actuator is operated. Thus, such an approach is not effective for preventing the problem of insulation breakdown of the piezoelectric substance.

On the other hand, in the case such a sidewall protective film is formed by an organic insulation film, adherence of the protective film to the laminated piezoelectric body is tend to be deteriorated, and there arises a problem that the sidewall protective film drops out when the piezoelectric actuator is operated.

In order to attend to this problem, it is conceivable to form the sidewall protective films by a vacuum process such as sputtering process or CVD process. However, such an approach of using a vacuum process is expensive and also increases the time needed for the protective film, and hence manufacturing the piezoelectric actuator.

In a first aspect of the present invention, there is provided a piezoelectric actuator, comprising:

a body of a piezoelectric material;

electrode patterns embedded in said body; and

a sidewall protective film of a piezoelectric material covering at least a sidewall surface of said body,

said sidewall protective film covering said electrode patterns at said sidewall surface of said body.

Further, the present invention provides a magnetic disk apparatus that uses such a piezoelectric actuator.

In another aspect, the present invention provides a method for manufacturing a piezoelectric actuator, comprising the steps of:

forming a liquid state film of a piezoelectric ceramic source material containing therein an organic metal compound on a surface of a body of a piezoelectric material by a coating process, said body of piezoelectric material including therein electrode patterns; and

forming a protective film of a piezoelectric material on said surface of said body from said liquid state piezoelectric ceramic source material.

According to the present invention, in which the electrode patterns exposed at the sidewall surfaces of the piezoelectric body forming the piezoelectric actuator are covered with the sidewall protective film of the piezoelectric ceramic material, it becomes possible to avoid the insulation breakdown at the sidewall surfaces, even in the case the piezoelectric actuator is used in a high temperature and high humidity ambient, and it becomes possible to operate the piezoelectric actuator or an electronic apparatus such as a magnetic head assembly that uses the piezoelectric actuator stably, in wide variety of ambient and environments.

Other objects and further features of the present invention will become apparent from the following detailed description when read in conjunction with the attached drawings.

### BRIEF DESCRIPTION OF THE DRAWINGS

FIG. 1 is a diagram showing the construction of a piezoelectric actuator according to a related art of the present invention;

FIGS. 2A and 2B are diagrams explaining a related art of the present invention;

FIG. 3 is a diagram explaining the related art of the present invention and those of the present invention;

FIG. 4 is a diagram showing the construction of a piezoelectric actuator according to a first embodiment of the present invention in an oblique view;

FIG. 5 is a longitudinal cross-sectional diagram showing the construction of the piezoelectric actuator of the first embodiment;

FIG. 6 is an oblique view diagram showing the construction of the piezoelectric actuator of the first embodiment;

FIGS. 7A-7C are diagrams showing the manufacturing process of the piezoelectric actuator of the first embodiment;

FIG. 8 is a diagram showing a time change of the insulation resistance of the piezoelectric actuator of the first embodiment in a high temperature and high humidity ambient;

FIG. 9 is a diagram showing the construction of the piezoelectric actuator used in the experiment of FIG. 8;

FIG. 10 is an end-view diagram showing the construction of the piezoelectric actuator according to a modification of the first embodiment;

FIG. 11 is a diagram showing construction of a magnetic head assembly according to a second embodiment of the present invention; and

FIG. 12 is a diagram showing the construction of a magnetic disk apparatus according to a third embodiment of the present invention.

### DETAILED DESCRIPTION OF THE INVENTION

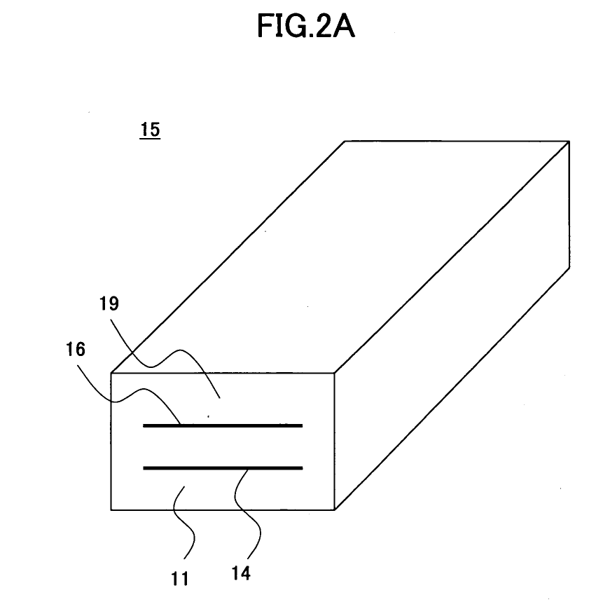

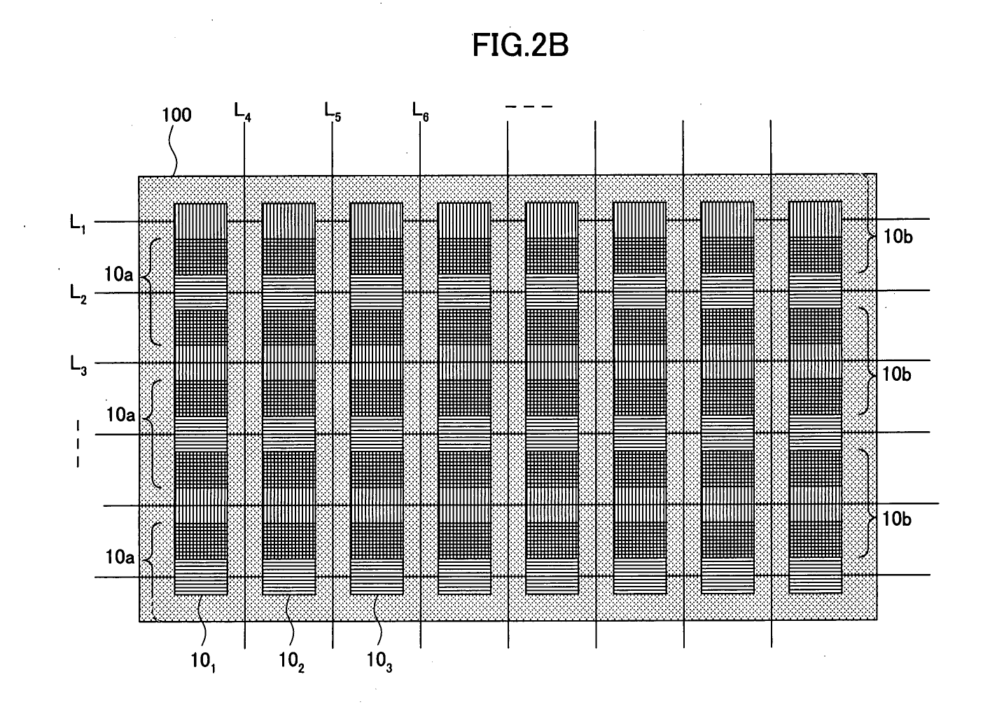

In order to solve the problems explained previously, it is conceivable to form the sidewall protective film integrally with the piezoelectric laminated body as in the case of a piezoelectric actuator 15 shown in FIG. 2A by using the same piezoelectric material. Thus, FIG. 2A, and also FIG. 2B to be explained below, shows a conceivable approach for attending to the problem explained before as a related art of the present invention.

The construction of FIG. 2A can be formed by increasing the separation between the device electrode patterns 10₁, 10₂, 10₃, . . . formed parallel on a baked substrate 100 as shown in FIG. 2B and by dicing the baked substrate along dicing lines L₁, L₂, L₃, . . . L₄, L₅, L₆, . . . . In FIG. 2B, it should be noted that those parts corresponding to the parts explained previously are designated by the same reference numerals and the description thereof will be omitted.

Further, in FIG. 2A, it should be noted that only the piezoelectric substance 11 and 19 and the electrodes 14 and 16 are shown. Further, illustration of the electrode patterns 10A and 10B formed at both ends of the piezoelectric laminated structure is omitted.

Further, in FIG. 2B, it should be noted that the electrode pattern 10a corresponds to the lower electrode pattern 14 of FIG. 2A, while the electrode pattern 10b corresponds to the upper electrode pattern 16 of FIG. 2A.

With the piezoelectric actuator 15 of such a construction, in which the sidewall protective film protecting the sidewall surface is formed integrally with the piezoelectric lamination body, it is expected that the problem of insulation breakdown or dropping out of the sidewall protective film is eliminated successfully.

In the case of forming such a structure on a baked substrate shown in FIG. 2B, on the other hand, it should be noted that the electrode patterns have to be formed on ceramic green sheets, from which the piezoelectric substance are formed, by way of screen printing and laminate the green sheets thus formed to form a laminated green sheet body. Further, the laminated green sheet body thus formed is subjected to a baking process.

When such a baking process is conducted, however, the piezoelectric lamination body shows a large shrinkage and it is difficult to suppress the positional error of the electrode patterns within several microns after the baking process.

Thus, when attempt is made to form a sidewall protective film covering the electrode patterns at the sidewall surface of the laminated body with the construction of FIG. 2A, it is necessary to set the thickness of such a sidewall protective film to be several ten microns in view of the possible error of formation of the electrode patterns on the baked substrate and in view of possible error at the time of the dicing process of the baked substrate. Otherwise, there is a possibility that the electrode pattern 14 or 16 is exposed at the sidewall surface of the piezoelectric lamination body after the dicing process and the insulation of the piezoelectric actuator is affected adversary by the high temperature and high humidity ambient. Thereby, there is a possibility that the problem of insulation breakdown is not resolved.

Thus, when the sidewall protective film is formed on the sidewall surface of the piezoelectric lamination body constituting the piezoelectric actuator with the approach of FIGS. 2A and 2B, there is a need of securing a layer thickness of at least several ten microns for such a sidewall protective film.

However, when such a thick protective film having a thickness exceeding several ten microns is formed on the sidewall surface of the piezoelectric lamination body constituting a piezoelectric actuator, the protective film resists the deformation of the piezoelectric actuator and there is a possibility that the desired displacement is not attained for the piezoelectric actuator when the piezoelectric actuator is activated.

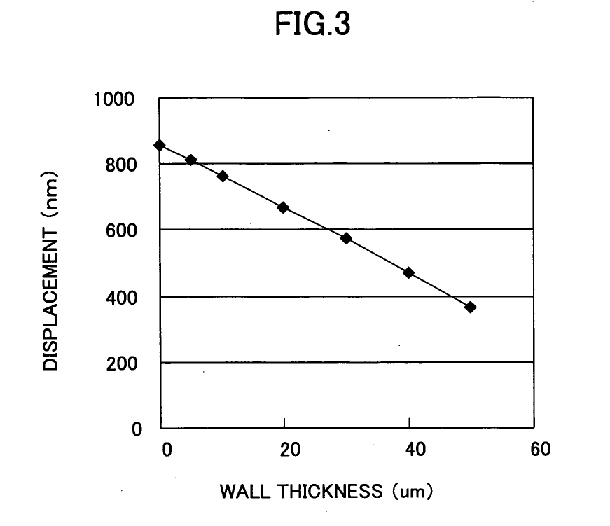

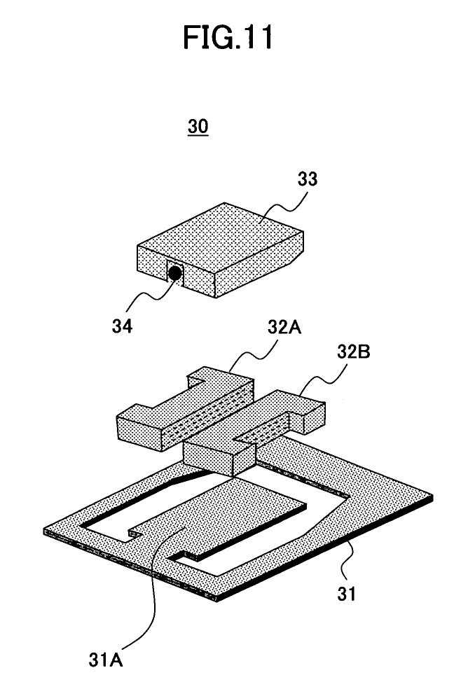

FIG. 3 is a diagram showing the change of magnitude of displacement of a magnetic head 34 for the case in which the thickness of the sidewall protective insulation film is changed from 0 μm to 50 μm in piezoelectric actuators 32A and 32B of FIG. 11 to be explained later. In FIG. 3, it should be noted that the piezoelectric actuators have an identical structure and are driven under an identical condition.

Referring to FIG. 3, it can be seen that the magnitude of displacement takes the value of 800 nm in the case there is provided no sidewall protective film, while the magnitude of displacement decreases with increase of the thickness of the sidewall protective film and falls below 400 nm, less than one-half of the initial magnitude, when the sidewall protective film has a thickness of 50 μm.

Thus, formation of sidewall protective film on the piezoelectric actuator contradicts to the improvement of driving performance of the piezoelectric actuator, and it has been difficult to arbitrate these two contradictory requirements by using a low cost construction.

### First Embodiment

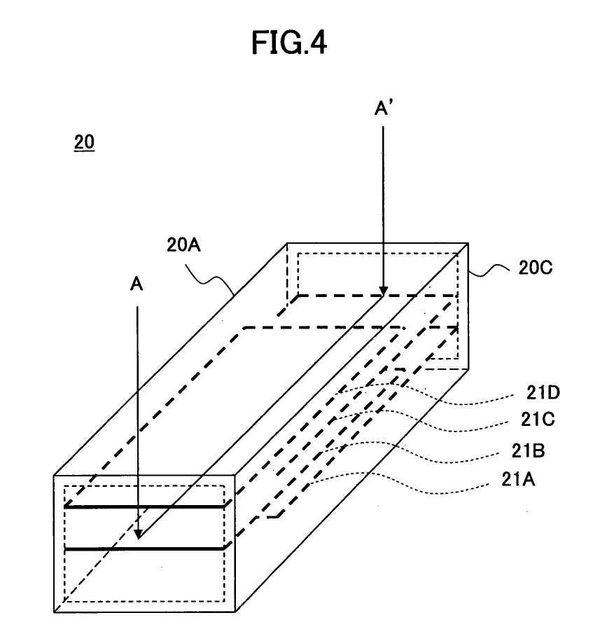

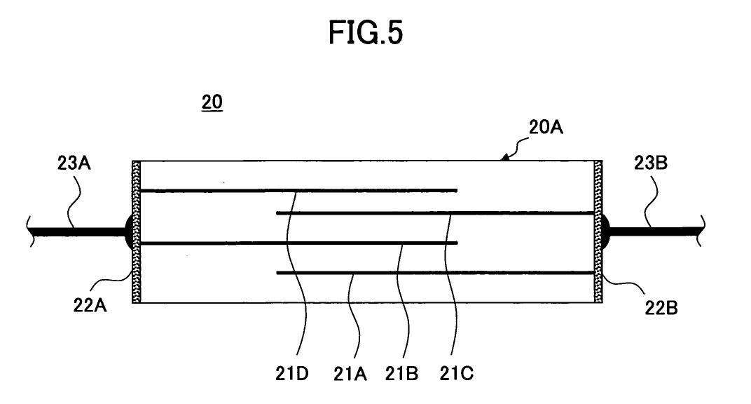

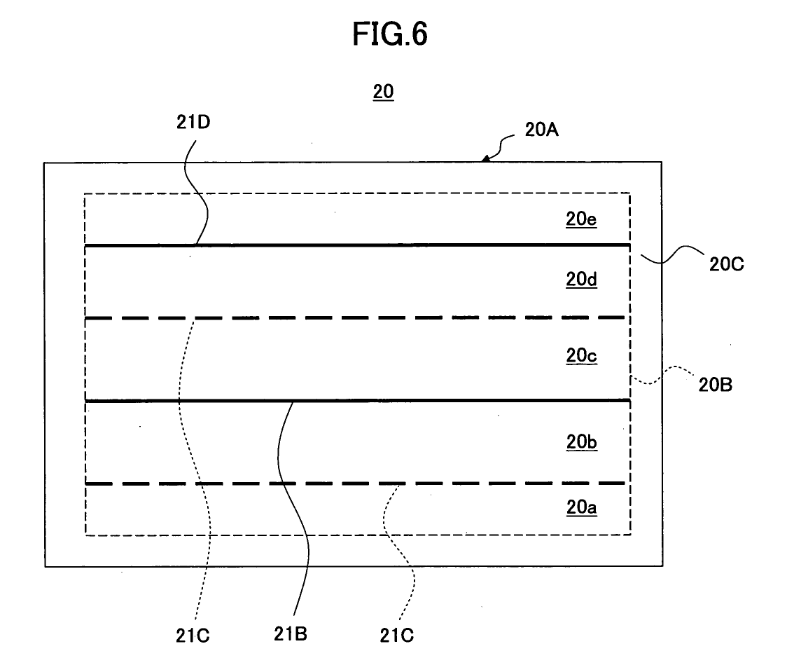

FIG. 4 is an oblique view diagram showing the construction of a piezoelectric actuator 20 according to a first embodiment of the present invention, while FIG. 5 shows the piezoelectric actuator 20 of FIG. 4 in a longitudinal cross-sectional view taken along a line A-A′ of FIG. 4. Further, FIG. 6 is a diagram showing the piezoelectric actuator 20 of FIG. 4 in an end view.

Referring to FIG. 4, the piezoelectric actuator 20 has an actuator body 20A formed of a piezoelectric material such as PZT or PNN, wherein electrode patterns 21A, 21B, 21C and 21D of a temperature-resistant metal martial of Pt or PtRh are embedded in the actuator body 20A.

As shown in the longitudinal cross-sectional view of FIG. 5, the electrode patterns 21A and 21C are exposed at one end surface of the actuator body 20A and covered with an electrode pad 22A also of a temperature-resistant metal such as Au formed on the first end surface. Similarly, the electrode patterns 21B and 21D are exposed at a second end surface and covered with an electrode pad 22B formed on the second end surface.

Further, a lead wire 23A of a temperature-resistant metal such as Au is bonded to the electrode pad 22A, while a similar lead wire 23B is bonded to the electrode pad 22B.

Typically, the piezoelectric actuator body 20A includes a piezoelectric lamination body 20B having a rectangular parallelepiped shape with a length of 1 mm, width of 0.25 mm and height of 0.25 mm, wherein the piezoelectric lamination body 20B is formed by laminating the piezoelectric substance 20a-20e and electrode patterns 21A-21D alternately as can be seen in the end view of FIG. 6. Further, the peripheral part of the piezoelectric lamination body 20B including the sidewall surfaces where the electrode patterns 21A-21D are exposed, is covered with a piezoelectric substance 20C. In FIG. 6, illustration of the electrode pads 22A and 22B is omitted.

The piezoelectric substance 20C is formed by a coating process such as dip-coating process and is formed to have a thickness of 25 μm or less, preferably 10 μm or less, typically 2-3 μm. In view of obtaining excellent adherence to the lamination body 20B, it is preferable that the piezoelectric substance 20C has a crystal structure and a composition identical to those of the piezoelectric substance 20a-20e constituting the piezoelectric lamination body 20B. However, it is also possible that the piezoelectric substance 20C has a different composition.

In the case of forming the piezoelectric substance 20C to have a different composition, it is preferable that the piezoelectric substance 20C has a crystal structure identical to that of the piezoelectric substance 20a-20e, such as a perovskite structure.

Because the piezoelectric substance 20C is formed by a dip-coating process, it is easy to form the piezoelectric substance 20C to have a thickness of 25 μm or less. Preferably the piezoelectric substance 20C is formed to have a thickness of 10 μm or less, more preferably 2-3 μm, as noted previously.

As a result, the decrease of magnitude of displacement of the piezoelectric actuator is held minimum, even when there is caused the problem of decrease of displacement of the piezoelectric actuator because of formation of the piezoelectric substance 20C around the lamination body 20B of the piezoelectric actuator 20.

In FIG. 3, for example, it can be seen that a displacement of 600 nm is secured in the case the piezoelectric substance 20C is formed with the thickness of 25 μm. In the case there is provided no piezoelectric substance 20C, it should be noted that the displacement attained is about 850 nm.

Further, in the case the piezoelectric substance 20C is formed with the thickness of 10 μm, it can be seen that a displacement exceeding 700 nm is attained. Further, in the case the piezoelectric substance 20C is formed with the thickness of 2-3 m, a displacement of about 800 nm is attained, while it should be noted that this amount of displacement is quite close to the displacement attained in the case the piezoelectric substance 20C is not provided around the piezoelectric lamination body 20B in view of the relationship of FIG. 3.

On the other hand, when the thickness of the piezoelectric substance 20C is reduced further and the layer thickness falls below 1 μm, there is a concern that sufficient insulation resistance may not be secured. Thus, there is a need of forming the piezoelectric substance 20C to have a thickness of 1 μm or more.

Here, it should be noted that the relationship of FIG. 3 is obtained by the inventor of the present invention in the investigation that constitutes the foundation of the present invention.

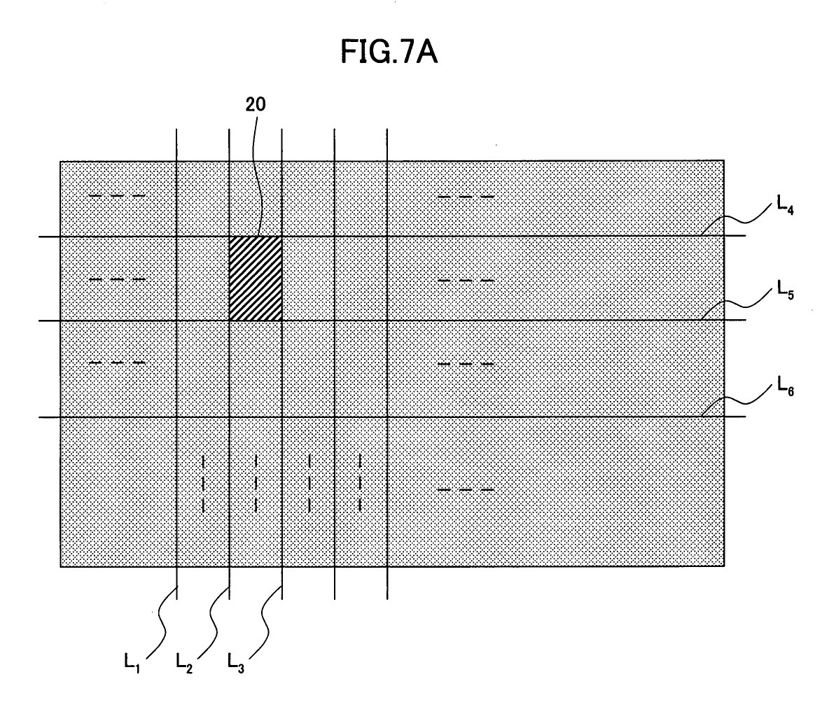

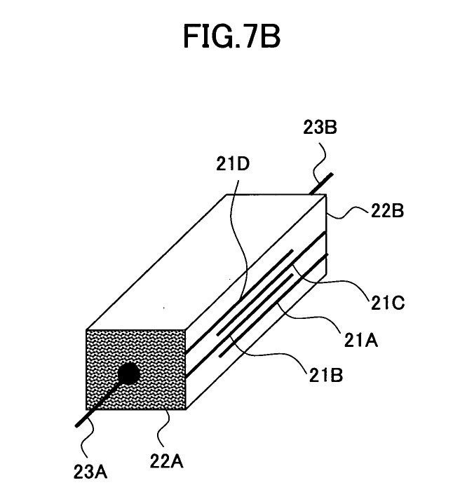

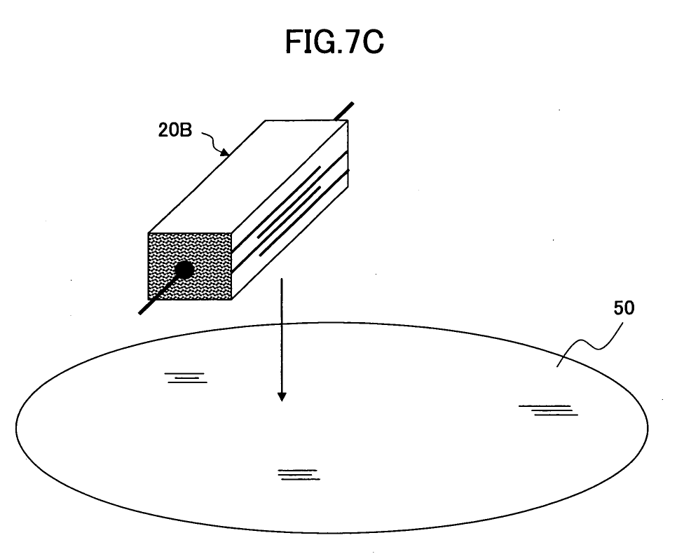

Next, manufacturing process of the piezoelectric actuator 20 of FIGS. 4-6 will be described with reference to FIGS. 7A and 7B.

Referring to FIG. 7A, electrode patterns corresponding to any of the electrode patterns 20A-20D of the piezoelectric actuator 20 are screen-printed side-by-side on green sheets of a piezoelectric material each constituting one of the piezoelectric substance 20a-20e.

The green sheets thus formed with the electrode patterns are then laminated and, after conducting a degreasing process, the resultant green laminate is subjected to a baking and crystallizing process. With this, a baked piezoelectric substrate is obtained such that the substrate includes therein the piezoelectric actuator elements in the state aligned in rows and columns.

Next, in the step of FIG. 7B, the baked piezoelectric substrate of FIG. 7A is subjected to a dicing process, and the individual piezoelectric actuator elements are separated from each other as piezoelectric actuators. With the piezoelectric actuator element formed by such a dicing process, it should be noted that the electrode patterns 21A-21D are exposed at the sidewall surfaces thereof, and thus, the piezoelectric actuator element of FIG. 7B corresponds to the lamination body 20B of FIG. 6.

Further, in the step of FIG. 7B, Au electrode films 22A and 22B are formed at respective end surfaces of the lamination body 20B of the piezoelectric actuator thus obtained by dicing, together with Au lead wires 23A and 23B.

Further, in the step of FIG. 7C, the lamination body 20B of FIG. 6 is dipped into a metal organic liquid source 50 of a piezoelectric material having a composition identical to or nearly identical to that of the piezoelectric substance 20a-20e, such as PZT or PNN, wherein it is preferable that the piezoelectric material formed from the metal organic liquid source 50 has a perovskite crystal structure. With this, there is formed a coating of the metal organic liquid source 50 around the lamination body 20B.

After the step of FIG. 7C, the lamination body 20B is pulled up from the liquid source 50, and after drying at 200° C. and pyrolitic decomposition conducted at 450° C., a crystallizing process is conducted at the temperature of 650° C., and with this, the piezoelectric material film 20C is formed around the lamination body 20B.

During such a crystallizing process, there can be a case in which volatile metal such as Pb in the piezoelectric material film 20C causes vaporization, and thus, there are cases in which the composition of the piezoelectric substance 20C does not coincide with the composition of the piezoelectric substance 20a-20e constituting the lamination body 20B, even when the liquid source 50 is prepared to provide the piezoelectric substance 20C with the composition identical to those of the piezoelectric substance 20a-20e.

Thus, in order to form the piezoelectric substance 20C with the composition as close to the composition of the piezoelectric substance 20a-20e, there are cases to increase the concentration of the volatile metal element such as Pb in the metal organic liquid source 50 beyond the nominal composition value corresponding to the composition of the piezoelectric substance 20C.

### EXAMPLE

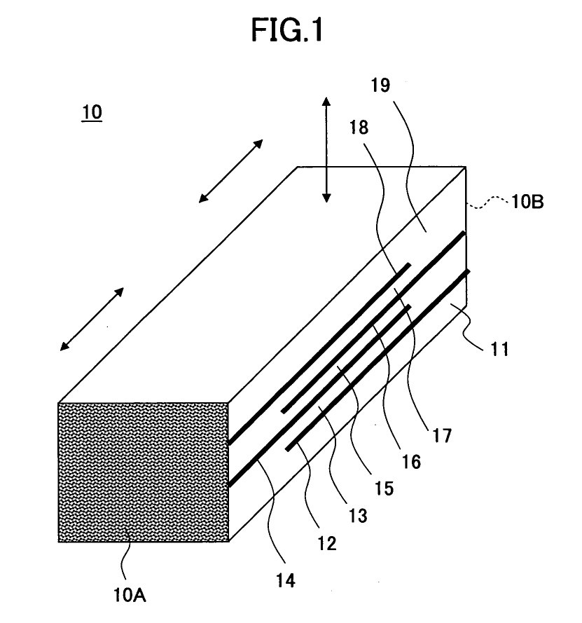

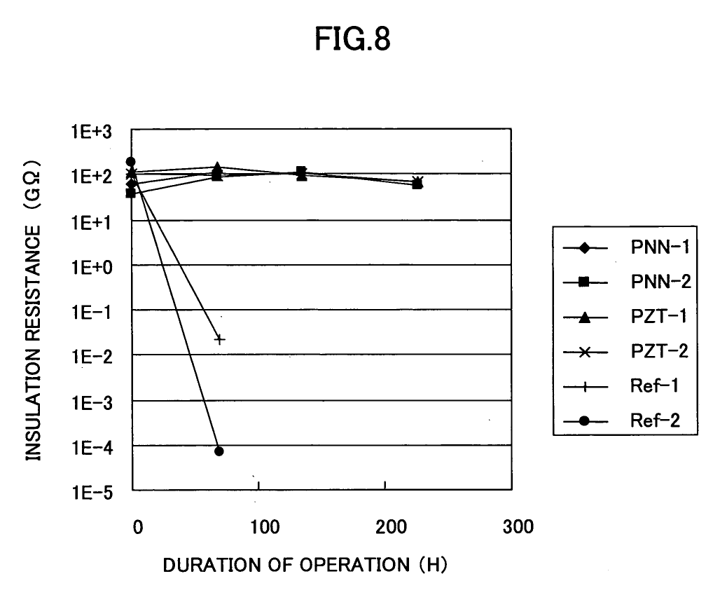

FIG. 8 is a diagram showing the relationship between the insulation resistance and duration of operation of the piezoelectric actuator 20 explained with reference to FIGS. 4-6 in comparison with the piezoelectric actuator 10 of FIG. 1 formed with identical size.

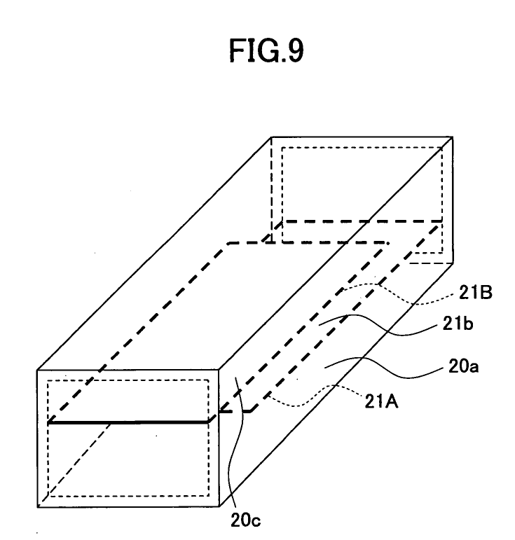

In the experiment of FIG. 8, it should be noted that the lamination body 20B is formed of three piezoelectric substance 20a-20c having a thickness of 40 μm as showing in FIG. 9, and thus, there are formed two electrode patterns 21A and 21B in the lamination body 20B.

In the experiment of FIG. 8, a PZT film is used for the piezoelectric substance 20a-20e, while for the piezoelectric substance 20c, a PZT film (represented as PZT-1 and PZT-2 in FIG. 8) or a PNN—PT-PZ piezoelectric substance (represented as PNN-1 and PNN-2 in FIG. 8) of a PNN—PT-PZ (Pb(Ni_{1/3}Nb_{2/3})O₃)_{0.5}—(PbTiO₃)_{0.35}—(PbZrO₃)_{0.15} system is used with the thickness of 2-3 μm. Further, in the drawing, it should be noted that “Ref-1” and “Ref-2” represent the case in which the piezoelectric substance 20C is omitted.

The experiment was conducted by applying a pulse voltage of 1 kH frequency with a peak-to-peak voltage of about 60V while holding the piezoelectric actuator in the ambient of 80° C. and humidity of 80%.

Further, with the experiment of FIG. 8, the piezoelectric actuator was formed to have a length of 4 mm, width of 1 mm and height of 0.25 mm.

Referring to FIG. 8, it can be seen that, in the case the piezoelectric substance 20C is not provided and the electrode patterns are exposed at the sidewall surfaces of the lamination body 20B (Ref-1, Ref-2), an initial insulation resistance, having a value exceeding 100 GΩ, has decreased to below 100 MΩ after operation for 70 hours.

In the case the piezoelectric substance 20C is provided by a PZT substance of the thickness of 2-3 μm (PZT-1, PZT-2), on the other hand, it can be seen that the insulation resistance exceeding 10 GΩ is maintained even when the operation of the actuator is continued over 200 hours.

It should be noted that, because the piezoelectric substance 20C is formed with a thickness of 2-3 μm, there arises no problem explained with reference to FIG. 3 that the magnitude of displacement of the piezoelectric actuator is decreased.

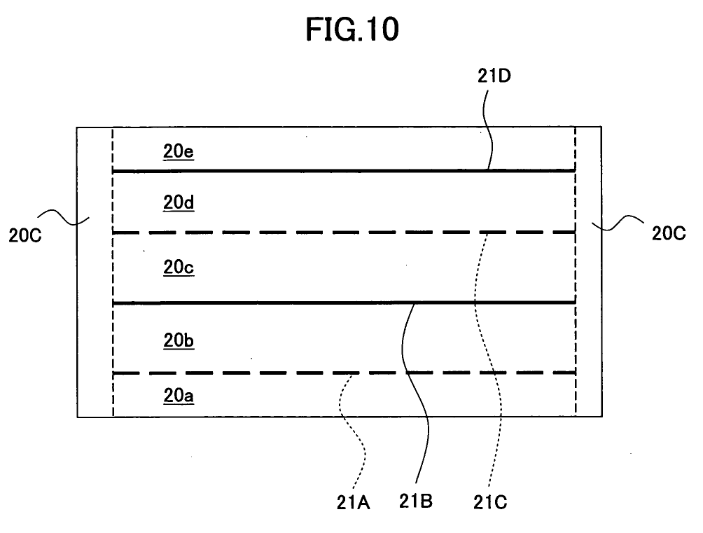

While the example of FIGS. 4-6 show the case in which the piezoelectric substance 20C covers not only the sidewall surfaces but also the top and bottom surfaces, it is important that the piezoelectric substance 20C covers the sidewall surfaces of the lamination body 20B, and thus, it is possible that the top and bottom surfaces are left uncovered by the piezoelectric substance 20C as shown in the end view of FIG. 10. In FIG. 10, too, illustration of the electrode patterns 22A and 22B on the end surfaces is omitted.

While the present embodiment was explained for the example of using a perovskite material containing Pb for the piezoelectric substance 10a-20e and further for the piezoelectric substance 20C, the present invention is not limited to such a specific piezoelectric material, and thus, it is also possible to use other piezoelectric materials. Further, the material of the electrodes 21A-21D is not limited to Pt but it is also possible to use other temperature-resistant metals such as a Pt—Rh alloy or a Pt—Ru alloy. Further, the electrode pads 22A and 22B or the lead wires 23A or 23B are not limited to Au.

### Second Embodiment

FIG. 11 shows the construction of a magnetic head assembly 30 according to a second embodiment of the present invention.

Referring to FIG. 11, the magnetic head assembly 30 includes a suspension 31 including a gimbal plate 31A, wherein piezoelectric elements 32A and 32B, each formed of the piezoelectric actuator 20 of FIGS. 4-6, are mounted on the gimbal plate 31A by an adhesive. It should be noted that these piezoelectric elements 32A and 32B were used in the experiment of FIG. 3 explained before.

Further, there is provided a head slider 33 of a ceramic material and carrying a magnetic head is attached over the piezoelectric actuators 32A and 32B also by an adhesive so as to bridge the piezoelectric elements 32A and 32B.

With the magnetic disk apparatus that uses such a magnetic head assembly 30, degradation of insulation resistance of the piezoelectric actuator is suppressed even when the magnetic disk is operated under a high temperature and humid ambient, and stable and reliable operation is guaranteed.

### Third Embodiment

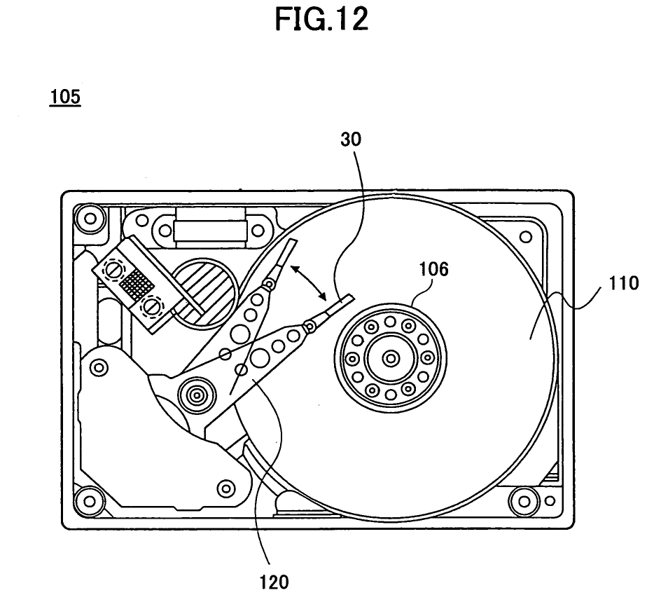

FIG. 12 is a diagram showing the construction of a magnetic recording apparatus 105 that uses a magnetic head assembly 30 of FIG. 11.

Referring to FIG. 12, the magnetic recording apparatus 105 includes a magnetic disk 110 rotated by a spindle motor 106, and there is provided an arm 120 scanning the surface of the magnetic disk 110 in a generally radial direction, wherein the arm 120 carries the magnetic head assembly 30 explained before on a distal end part thereof, and the magnetic head assembly 30 scans over the surface of the magnetic disk 110 with a predetermined floating distance.

With the magnetic recording apparatus 105 of such a construction, the electrodes of the piezoelectric actuators are protected by a thin protective substance of a piezoelectric ceramic material not resisting the operation of the piezoelectric actuator on the sidewall surfaces thereof, and high reliability is attained even when the magnetic recording apparatus is operated in a high temperature and humid ambient.

While the present invention has been explained for preferred embodiments, the present invention is not limited to such specific embodiments but various variations and modifications may be made without departing from the scope of the invention.

What is claimed is:

1. A piezoelectric actuator, comprising:
a body of a piezoelectric material;
electrode patterns embedded in said body; and
a sidewall protective film of a piezoelectric material covering at least a sidewall surface of said body,
said sidewall protective film covering said electrode patterns at said sidewall surface of said body.

2. The piezoelectric actuator as claimed in claim 1, wherein said sidewall protective film covers said sidewall surface with a layer thickness of 25 μm or less.

3. The piezoelectric actuator as claimed in claim 1, wherein said sidewall protective film covers said sidewall surface with a layer thickness of 10 μm or less.

4. The piezoelectric actuator as claimed in claim 1, wherein said sidewall protective film covers said sidewall surface with a layer thickness of 2-3 μm.

5. The piezoelectric actuator as claimed in claim 1, wherein said sidewall protective film has a crystal structure identical to a crystal structure of said piezoelectric material constituting said body.

6. The piezoelectric actuator as claimed in claim 1, wherein said sidewall protective film has a composition identical to a composition of said piezoelectric material constituting said body.

7. A magnetic disk apparatus, comprising:
a rotary magnetic disk;
an arm scanning a surface of said magnetic disk in a generally radial direction; and
a piezoelectric actuator held on said arm and carrying thereon a magnetic head,
said piezoelectric actuator comprising:
a body of a piezoelectric material;
electrode patterns embedded in said body; and
a sidewall protective film of a piezoelectric material covering at least a sidewall surface of said body,
said sidewall protective film covering said electrode patterns at said sidewall surface of said body.

8. A method for manufacturing a piezoelectric actuator, comprising the steps of:
forming a liquid state film of a piezoelectric ceramic source material containing therein an organic metal compound on a surface of a body of a piezoelectric material by a coating process, said body of piezoelectric material including therein electrode patterns; and
forming a protective film of a piezoelectric material on said surface of said body from said liquid state piezoelectric ceramic source material.

9. The method as claimed in claim 8, wherein said coating process being conducted by dipping said body into said liquid state piezoelectric ceramic source material.

10. The method as claimed in claim 8, wherein any of said piezoelectric material constituting said body and said liquid state piezoelectric ceramic source material contains Pb, and wherein said liquid state piezoelectric ceramic source material contains Pb such that said protective film has a Pb concentration larger than a Pb concentration of said piezoelectric material constituting said body.
